(19) United States
(12) Patent Application Publication
(10) Pub. No.: US 2025/0297855 A1
(43) Pub. Date: Sep. 25, 2025

(54) SYSTEM AND METHOD FOR DEVICE-LIKE OVERLAY TARGETS MEASUREMENT

(71) Applicant: KLA Corporation, Milpitas, CA (US)

(72) Inventors: Vladimir Levinski, Migdal HaEmek (IL); Nireekshan K. Reddy, Tel Aviv (IL)

(21) Appl. No.: 18/612,383

(22) Filed: Mar. 21, 2024

(51) Int. Cl. G01B 11/27; G03F 7/00

(52) U.S. Cl. CPC G01B 11/272; G03F 7/70633; G03F 7/70666; G03F 7/706849

(57) ABSTRACT

A method may include illuminating an overlay target of a sample with one or more broadband illumination beams from one or more broadband illumination sources. The overlay target may include one or more meta-lens feature sets. Each meta-lens feature set may include one or more first features having a coarse pitch and one or more second features having a fine pitch. The one or more first features and the one or more second features of each meta-lens feature set may operate as a meta-lens array to generate a periodic distribution of light at a measurement plane. The method may further include generating one or more images of the periodic distribution of light at the measurement plane. The method may further include generating an overlay measurement of the sample based on the one or more images of the periodic distribution of light at the measurement plane.

### TECHNICAL FIELD

The present disclosure relates generally to overlay metrology and, more particularly, to a system and method for device-like overlay targets measurement.

### BACKGROUND

Overlay metrology generally refers to measurements of the relative alignment of layers on a sample such as, but not limited to, semiconductor devices. An overlay measurement, or a measurement of overlay error, typically refers to a measurement of the misalignment of fabricated features on two or more sample layers. In a general sense, proper alignment of fabricated features on multiple sample layers is necessary for proper functioning of the device.

Demands to decrease feature size and increase feature density are resulting in correspondingly increased demand for accurate and efficient overlay metrology. Metrology systems typically generate metrology data associated with a sample by measuring or otherwise inspecting dedicated metrology targets distributed across the sample.

Many of the current targets are noncompliant with design rules and not process compatible. For example, the grating may have dimensions that are noncompliant with design rules. For instance, the typical size of a feature or a space in the target may be hundreds of nanometers, in contrast with design rule features, which are tens of nanometers in size. Further, the pitch of the segmented features may be similar to the design rules, but the space between such features is not design rule compliant, e.g., having a size of hundreds of nanometers. This leads to damaged targets with sub-optimal metrology performance. In addition, even excellent quality targets may not reflect the overlay of the device because overlay induced by the scanner and other processes may depend on feature size, density, and pitch. Current targets that are process compatible, like critical dimension (CD) modulation targets, have measurability problems. For example, the printed patterns of the CD modulation targets are hardly measurable, even when using a dark imaging optical configuration.

As such, it would be advantageous to provide a system and method for device-like overlay targets measurement that cures the shortcomings of the previous approaches identified above.

### SUMMARY

An overlay metrology target is disclosed, in accordance with one or more embodiments of the present disclosure. In embodiments, the overlay metrology target includes one or more first exposure structures. In embodiments, the overlay metrology target includes one or more second exposure structures, wherein at least one of the one or more first exposure structures or the one or more second exposure structures include one or more meta-lens feature sets. In embodiments, each meta-lens feature set includes one or more first features having a coarse pitch and one or more second features having a fine pitch, where the one or more second features are positioned relative to the one or more first features, where the fine pitch is smaller than the coarse pitch. In embodiments, the one or more first features and the one or more second features of each meta-lens feature set operate as a meta-lens array to generate a periodic distribution of light at a measurement plane different than a plane of at least one of the one or more meta-lens feature sets, where the periodic distribution of light has the coarse pitch.

A meta-lens feature set is disclosed, in accordance with one or more embodiments of the present disclosure. In embodiments, the meta-lens feature set includes one or more first features having a coarse pitch and one or more second features having a fine pitch, where the one or more second features are positioned relative to the one or more first features, where the fine pitch is smaller than the coarse pitch. In embodiments, the one or more first features and the one or more second features operate as a meta-lens array to generate a periodic distribution of light at a measurement plane different than a plane of the meta-lens feature set, where the periodic distribution of light has the coarse pitch.

An overlay metrology system is disclosed, in accordance with one or more embodiments of the present disclosure. In embodiments, the system includes an illumination sub-system including one or more broadband illumination sources configured to generate one or more broadband illumination beams and one or more illumination optics configured to direct the one or more broadband illumination beams to an overlay target on a sample when implementing a metrology recipe, where the overlay target in accordance with the metrology recipe includes one or more meta-lens feature sets, where each meta-lens feature set includes one or more first features having a coarse pitch and one or more second features having a fine pitch, where the one or more first features and the one or more second features of each meta-lens feature set operates as a meta-lens array to generate a periodic distribution of light at a measurement plane different than a plane of at least one of the one or more meta-lens feature sets, where the periodic distribution of light has the coarse pitch. In embodiments, the system includes a collection sub-system including a detector configured to generate one or more images of the periodic distribution of light at the measurement plane and one or more collection optics. In embodiments, the system includes a controller communicatively coupled to the detector, the controller including one or more processors configured to execute program instructions causing the one or more processors to: receive the one or more images of the periodic distribution of light at the measurement plane from the detector and generate an overlay measurement of the sample based on the one or more images of the periodic distribution of light at the measurement plane.

An overlay metrology system is disclosed, in accordance with one or more embodiments of the present disclosure. In embodiments, the system includes a controller communicatively coupled to a detector. In embodiments, the controller includes one or more processors configured to execute program instructions causing the one or more processors to: receive one or more images of a periodic distribution of light at a measurement plane from the detector, where the overlay target in accordance with the metrology recipe includes one or more meta-lens feature sets, where each meta-lens feature set includes one or more first features having a coarse pitch and one or more second features having a fine pitch, where the one or more first features and the one or more second features of each meta-lens feature set operates as a meta-lens array to generate the periodic distribution of light at the measurement plane different than a plane of at least one of the one or more meta-lens feature sets, where the periodic distribution of light has the coarse pitch; and generate an overlay measurement of a sample based on the one or more images of the periodic distribution of light at the measurement plane.

A method is disclosed, in accordance with one or more embodiments of the present disclosure. In embodiment, the method includes: illuminating an overlay target of a sample with one or more broadband illumination beams from one or more broadband illumination sources, where the overlay target in accordance with a metrology recipe includes one or more meta-lens feature sets, where each meta-lens feature set includes one or more first features having a coarse pitch and one or more second features having a fine pitch, where the one or more first features and the one or more second features of each meta-lens feature set operates as a meta-lens array to generate a periodic distribution of light at a measurement plane different than a plane of at least one of the one or more meta-lens feature sets, where the periodic distribution of light has the coarse pitch; generating one or more images of the periodic distribution of light at the measurement plane; receiving the one or more images of the periodic distribution of light at the measurement plane; and generating an overlay measurement of the sample based on the one or more images of the periodic distribution of light at the measurement plane.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A is a conceptual view of a critical dimension (CD) modulation feature set of an overlay metrology target.

FIG. 1B is a contrast simulation image of the critical dimension (CD) modulation feature set of the overlay metrology target shown in FIG. 1A.

FIG. 2 is a conceptual view of a meta-lens feature set, in accordance with one or more embodiments of the present disclosure.

FIG. 3 is a top view of an overlay target including the meta-lens feature set, in accordance with one or more embodiments of the present disclosure.

FIG. 4 is a conceptual view of a two-dimensional feature set, in accordance with one or more embodiments of the present disclosure.

FIG. 5A is simplified schematic view of an overlay metrology system including an overlay metrology sub-system, in accordance with one or more embodiments of the present disclosure.

FIG. 5B is a conceptual view of the overlay target including the meta-lens feature set, in accordance with one or more embodiments of the present disclosure.

FIG. 6 is a flowchart depicting a method for measuring overlay, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to a system and method for measurement of device-like overlay targets that provides sufficient target contrast and solves the measurement problems associated with CD modulation targets. For example, the system and method may enhance the contrast of the target by creating a focusing effect. For instance, the duty cycle variability within each pitch of the periodic target may be designed such that the phase distribution of the corresponding part of the zero-order plane wave goes through the target and back to resemble the lens phase distribution.

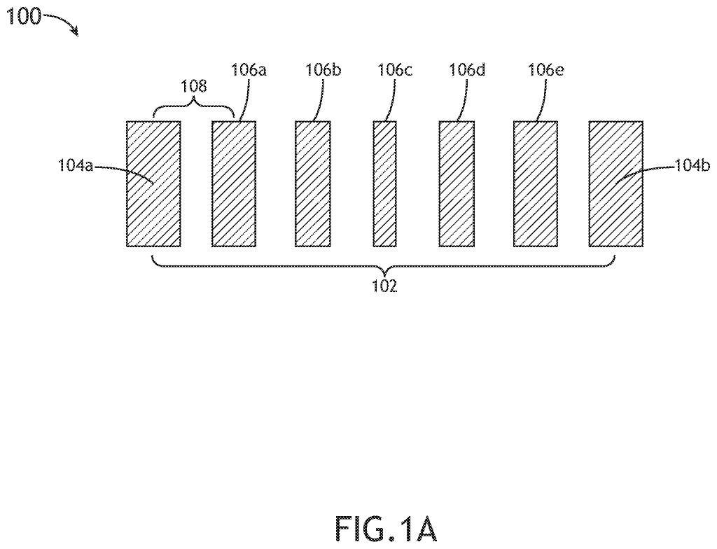

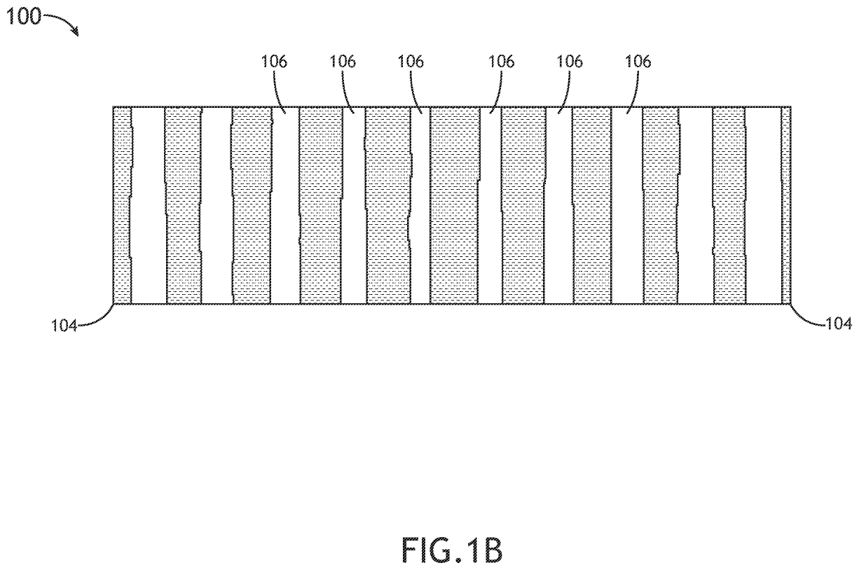

FIG. 1A is CD modulation feature set 100 including a device-like target design with fine pitch critical-dimension (CD) modulation.

The CD modulation feature set 100 may include a coarse pitch 102 between isolated features 104 (e.g., 104a, 104b, or the like) having spaces that are each filled with densely packed features 106 (e.g., 106a, 106b, 106c, 106d, 106e, or the like) that comply with predefined design rules. For example, the dense features 106a-106e may be positioned between isolated features 104a and 104b such that the coarse pitch 102 and densely packed features 106a-106e having a fine pitch 108 are all design rule compliant. Segmented scatterometry overlay targets are generally discussed in U.S. Pat. No. 8,913,237, issued on Dec. 16, 2014, which is incorporated herein by reference in the entirety.

As previously discussed herein, a target including the CD modulation feature set 100 (as shown in FIG. 1A) may be process compatible. However, it is noted herein that a target including the CD modulation feature set 100 (as shown in FIG. 1A) suffers from measurability problems when used in an imaging-based system. For example, FIG. 1B is a contrast simulation of the CD modulation feature set 100 shown in FIG. 1A. The contrast of the printed pattern of the target of the CD modulation feature set 100 is low such that the signal is hardly measurable, even when a dark-field imaging optical configuration is used.

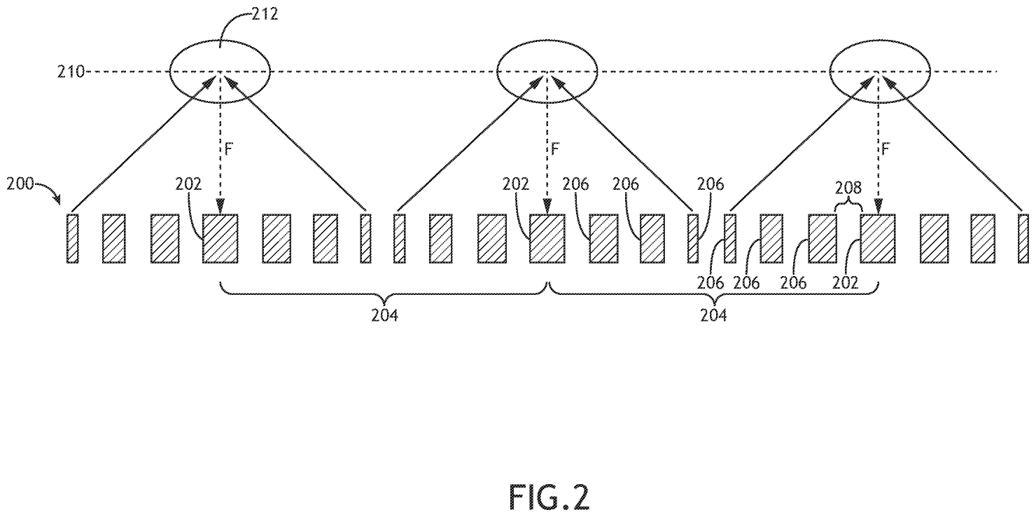

FIG. 2 is a meta-lens feature set 200, in accordance with one or more embodiments of the present disclosure.

In embodiments, the meta-lens feature set 200 includes one or more first features 202 having a coarse pitch 204.

In embodiments, the meta-lens feature set 200 includes one or more second features 206 having a fine pitch 208. For example, the one or more second features 206 may be positioned relative to the one or more first features 202, where the fine pitch 208 is smaller than the coarse pitch 204. Further, it is contemplated herein that the one or more first features 202 may have a first set of critical dimension values and the one or more second features 206 may have a second set of critical dimension values different from the first set of critical dimension values.

It is contemplated herein that the coarse pitch 204 and fine pitch 208 may be configured such that their ratio is a whole number (N). Accordingly, within the coarse pitch 204, N symmetric second features 206 with different geometrical characteristics may be printed, such that the distance between centers of the neighboring feature corresponds to the fine pitch 208. In this regard, the geometrical characteristics of the second features 206 may be configured such that N second features 206 within the coarse pitch 204 may work as a separate lens focusing the reflected light (e.g., 0-order light) at a measurement plane 210 some distance above a target.

In embodiments, the first features 202 and the second features 206 operate as a lens array to enhance contrast. For example, the first features 202 and the second features 206 may form a meta-lens feature set 200 formed of sub-resolution features to focus incident light (e.g., 0-order light) to a measurement plane 210 in a periodic distribution having the coarse pitch 204. In this regard, the position of the periodic distribution of light in the measurement plane 210 may be indicative of positions of the meta-lens feature set 200. It is contemplated herein that the fine pitch and/or the CD of any of the second features 206 may be sub-resolution features.

In embodiments, a duty cycle of the second features 206 may be varied. For example, the duty cycle of the second features 206 may be varied to resemble a lens phase distribution, where the lens phase distribution is based on a lens focus distance F (or focal length F). For instance, the phase difference may shift the focal location, such that the measurement plane 210 of the target 201 is arranged at the lens focus distance F.

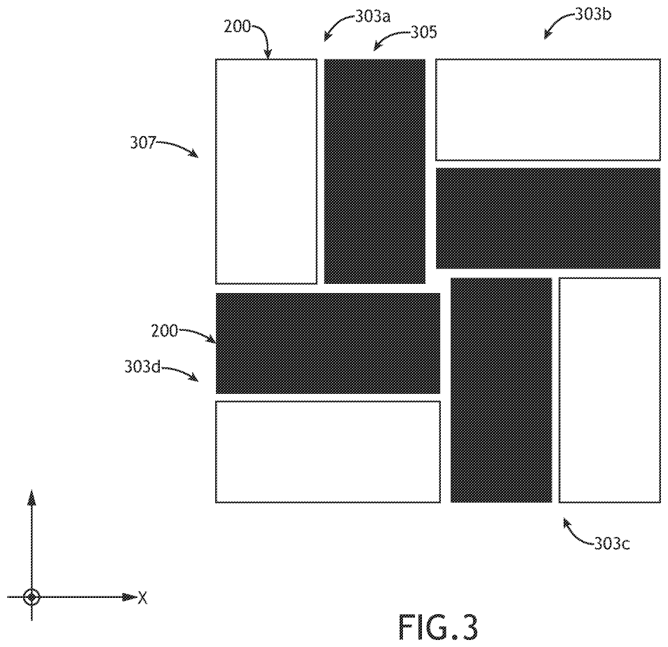

FIG. 3 is an overlay target 201 including one or more meta-lens feature sets 200 as shown in FIG. 2, in accordance with one or more embodiments of the present disclosure. It is contemplated herein that the overlay target 201 in FIG. 3 may be suitable for image-based overlay.

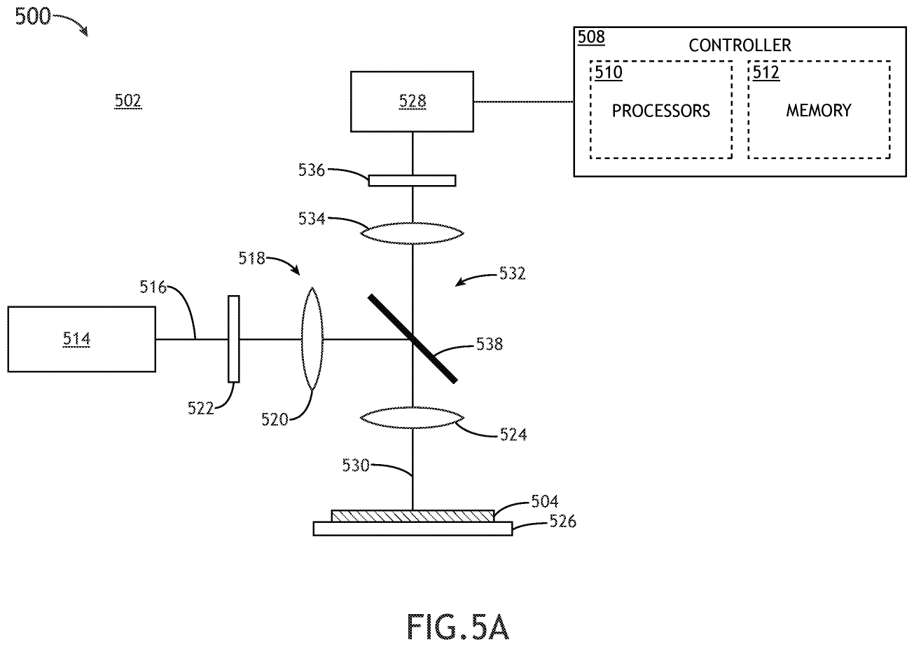

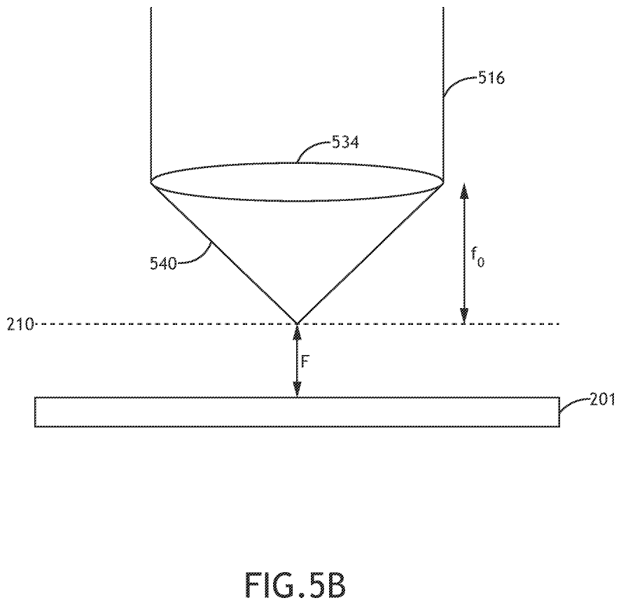

In embodiments, the overlay target 201 includes four cells 303a-d, represented here as quadrants of the overlay target 201. Each cell 303a-d may include first exposure structures 305 and second exposure structures 307. At least one of the first exposure structures 305 or the second exposure structures 307 may include one or more meta-lens feature sets 200. For example, in a non-limiting example, the resist layer and the process layer may include meta-lens features. Although FIG. 3. depicts the first exposure structure 305 and second exposure structure 307 of each cell 303a-d including meta-lens features, it is contemplated herein that one of the first exposure structure or the second exposure structure may include meta-lens feature sets. For example, in a non-limiting example, the resist layer may contain standard periodic features having no lens effect and the process layer may include meta-lens features, or vice versa. In this regard, the standard periodic features having no lensing effect may be imaged by moving the sample up to the bottom of the cone 540 (shown in FIG. 5B)

It is contemplated herein that the first exposure structures 305 may be associated with a first lithographic exposure and the second exposure structures 307 may be associated with a second lithographic exposure, where the first and second lithographic exposure may be on the same layer (or different layers as shown in FIG. 3).

Further, the cell 303b and cell 303d may be configured to provide overlay measurements along the X direction as illustrated in FIG. 3. For instance, an overlay measurement along the X direction may be made by directly comparing relative positions of the first-layer meta-lens feature sets 200 and the second-layer meta-lens feature sets 200 within each cell or between cell 303b and cell 303d. In another instance, an overlay measurement along the X direction may be made by comparing a point of symmetry (e.g., rotational symmetry, reflection symmetry, mirror symmetry, or the like) between first-layer meta-lens feature sets 200 distributed across cell 303b and cell 303d with a point of symmetry between second-layer printed meta-lens feature sets 200 distributed across cell 303b and cell 303d. Similarly, cell 303a and cell 303c may be configured to provide overlay measurements along the Y direction as illustrated in FIG. 3.

It is to be understood that the FIG. 3 is provided solely for illustrative purposes and should not be interpreted as limiting. The overlay target 201 may include any design of pattern elements for use in an imaging mode or in a scatterometry mode. For example, in some embodiments, the meta-lens feature sets 200 are non-overlapping structures, as shown in FIG. 3. By way of another example, in some embodiments, the meta-lens feature sets 200 may be overlapping structures.

The lens phase distribution may be defined by Eq. (1), as shown and described below:

$$φ ( x ) = - \frac{2 π}{λ} ( \sqrt{{F}^{2} + {x}^{2}} - F ) , \qquad Eq . ( 1 )$$

where F is the lens focus distance, λ is wavelength, and x is distance.

It is contemplated herein that features 202, 206 of the meta-lens feature set are smaller than the wavelength of the incident light (e.g., illumination of the system), such that the effective medium theory may be used to describe electromagnetic scattering. As such, using the effective medium approximation, the phase distribution of the part of zero order plane wave which goes through the target and back may be described using Eq. (2), as shown and described below:

$$φ ( x ) = \frac{4 π}{λ} {n}_{eff} ( x , λ ) \cdot H , \qquad Eq . ( 2 )$$

where H is the target height and n_{eff} is the polarization dependent effective refractive index for Y and X polarizations, respectively, as given by Eq. (3a) and Eq. (3b), as shown and described below:

$${n}_{eff}^{Y} = \sqrt{{ϵ}_{Gr} \cdot η ( x ) + {ϵ}_{Sur} \cdot ( 1 - η ( x ) ) ,} \qquad Eq . ( 3 a )$$

$${n}_{eff}^{X} = \sqrt{\frac{{ϵ}_{Gr} \cdot {ϵ}_{Sur}}{{ϵ}_{Gr} \cdot ( 1 - η ( x ) ) + {ϵ}_{Sur} \cdot η ( x )}} , \qquad Eq . ( 3 b )$$

where ϵ_{Gr} and ϵₛᵤᵣ are the permittivities of the inclusion (e.g., silicon, or the like) and the surrounding layers (e.g., oxide layer, or the like), respectively, and η(x) is the duty cycle of the segmentation in the x-direction.

It is contemplated herein that although the effective medium theory is used to describe electromagnetic scattering, other models/theories may be used such as, but not limited to, numerical scattering, or the like.

As previously discussed herein, it is contemplated herein that the meta-lens features set 200 including the first features 202 and second features 206 may function as a meta-lens array (e.g., an array of lenses having the coarse pitch) that generates a periodic distribution of light at the measurement plane 210, which may be imaged by the system. For example, the meta-lens array may have a predefined focusing distance F. Accordingly, at focus distance F from the meta-lens feature set 200, a periodic signal 212 with enhanced contrast (e.g., relative to an image of the meta-lens feature set 200 itself) may be detected to determine a grating position measurement. For example, for Y polarization, n_{eff} from Eq. (3a) may be substitute into Eq. (2) and equated to Eq. (1) yielding Eq. (4), as shown and described below:

$$\frac{4 π}{λ} \sqrt{{ϵ}_{Gr} \cdot η ( x ) + {ϵ}_{Sur} \cdot [ 1 - η ( x ) ]} \cdot H = - \frac{2 π}{λ} ( \sqrt{{F}^{2} + {x}^{2}} - F ) + const \qquad Eq . ( 4 )$$

$$where , const = \frac{4 π}{λ} \sqrt{{ϵ}_{Gr} \cdot η ( 0 ) + {ϵ}_{Sur} \cdot [ 1 - η ( 0 ) ]} \cdot H$$

In a non-limiting example, estimation of the focus distance F, for example, for silicon in oxide, gives the value of ˜1 μm. For example, for ϵ_{Gr}˜15 and ϵₛᵤᵣ˜2.5, Δn_{eff} is ˜1.5 (from dense to isolated structures). As such, the lens focus distance F may be

$$F ∼ \frac{{( \frac{coarse pitch}{2} )}^{2}}{4 Δ {n}_{eff} H} ∼ 1 μm ,$$

where the coarse pitch is ˜1 μm and H is ˜50 nm.

It is noted herein that one-dimensional gratings may be associated with dependence of target design on polarization direction of illumination light. For example, one-dimensional gratings require measuring X and Y targets with different polarizations (i.e., double grab) which increase the measurement time. As such, in some instances, it may be preferable to use two-dimensional targets to reduce measurement time and target size.

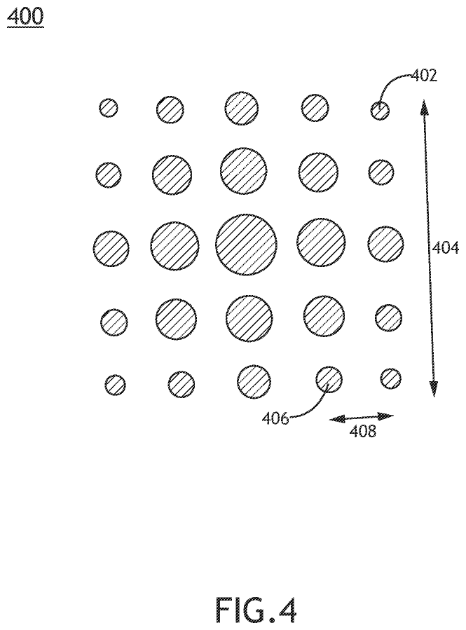

FIG. 4 is a two-dimensional feature set 400, in accordance with one or more embodiments of the present disclosure.

In embodiments, the meta-lens feature set 400 includes target features 402 in a y-direction having a target pitch 404.

In embodiments, the meta-lens feature set 400 includes design rule features 406 in a x-direction having a design rule pitch 408 (or fine pitch).

In embodiments, the target features 402 and the design rule features 406 may have the same pitch in the x- and y-directions. In this regard, the special structures within each unit cell which would provide polarization independent response. Further it is contemplated herein that the printed structure is configured in accordance with 90 degrees of rotational invariance.

Although FIG. 4 depicts the meta-lens feature set 400 including radial spatial modulation with circular inclusions, it is contemplated herein that the features may have any size, shape, or the like. For example, the inclusions may include, but are not limited to, square inclusions, a square lattice structure, a hexagonal structure, triangular structure, and the like suitable for a predetermined physical response.

Further, it is contemplated herein that an overlay target (similar to the target shown in FIG. 3) may include first exposure structures and second exposure structures, where at least one of the first exposure structures or the second structures includes one or more meta-lens features sets 400.

The phase function for the zero-order plane wave for focusing for a two-dimensional target may be described using Eq. (5), as shown and described below:

$$φ ( x , y ) = - \frac{2 π}{λ} ( \sqrt{{F}^{2} + {x}^{2} + {y}^{2}} - F ) , \qquad Eq . ( 5 ) .$$

It is noted that the phase distribution φ(x,y) may be any general function suitable for serving the focusing purposes and thus not limited to radial function. For instance, such a generalization can be readily extended to cylindrical lens as well. Similar to 1D case, the phase distribution over the target may described by effective medium theory as shown and described by Eq. (6) below:

$$φ ( x , y ) = \frac{4 π}{λ} {n}_{eff} ( x , y ) \cdot H , \qquad Eq . ( 6 )$$

In the case of two-dimensional periodic structures, it is noted herein that there is no analytical closed form expression for effective medium known in the literature. However, using Green's functions approach for periodic medium the corresponding expression for structures whose form is symmetric with respect to rotation by 90° can be obtained and it has the following form, as shown and described below with respect to Eq. (7):

$${n}_{eff} = \sqrt{{ϵ}_{Sur} \frac{{ϵ}_{Gr} \cdot ( 1 + η ) + {ϵ}_{Sur} \cdot ( 1 - η )}{{ϵ}_{Gr} \cdot ( 1 - η ) + {ϵ}_{Sur} \cdot ( 1 + η )} ,} \qquad Eq . ( 7 )$$

where η=S(x,y)/(Corase Pitch)², with S(x,y) being the spatially dependent area of inclusion ϵ_{Gr}. Assuming that the parameter n can vary from approximately 0.1 to 0.7 (e.g., due to printability and geometrical form of inclusion), Δn_{eff}˜1 and the corresponding focus distance (under the same conditions as in the example for one-dimensional target) is about 1.5 μm.

FIG. 5A is a conceptual view of an overlay metrology system 500 for performing overlay metrology on an overlay target 201 using a metrology sub-system 502, in accordance with one or more embodiments of the present disclosure.

It is noted herein that for the purposes of the present disclosure, the term “overlay” is generally used to describe relative positions of features on a sample fabricated by two or more lithographic patterning steps, where the term “overlay error” describes a deviation of the features from a nominal arrangement. In this context, an overlay measurement may be expressed as either a measurement of the relative positions or of an overlay error associated with these relative positions. For example, a multi-layered device may include features patterned on multiple sample layers using different lithography steps for each layer, where the alignment of features between layers must typically be tightly controlled to ensure proper performance of the resulting device. Accordingly, an overlay measurement may characterize the relative positions of features on two or more of the sample layers. By way of another example, multiple lithography steps may be used to fabricate features on a single sample layer. Such techniques, commonly called double-patterning or multiple-patterning techniques, may facilitate the fabrication of highly dense features near the resolution of the lithography system. An overlay measurement in this context may characterize the relative positions of the features from the different lithographic steps on this single layer. It is to be understood that examples and illustrations throughout the present disclosure relating to a particular application of overlay metrology are provided for illustrative purposes only and should not be interpreted as limiting the disclosure.

As used throughout the present disclosure, the term “sample” generally refers to a substrate formed of a semiconductor or non-semiconductor material (e.g., a wafer, or the like). For example, a semiconductor or non-semiconductor material may include, but is not limited to, monocrystalline silicon, gallium arsenide, and indium phosphide. A sample may include one or more layers. For example, such layers may include, but are not limited to, a resist, a dielectric material, a conductive material, and a semiconductive material. Many different types of such layers are known in the art, and the term sample as used herein is intended to encompass a sample on which all types of such layers may be formed. One or more layers formed on a sample may be patterned or unpatterned. For example, a sample may include a plurality of dies, each having repeatable patterned features. Formation and processing of such layers of material may ultimately result in completed devices. Many different types of devices may be formed on a sample, and the term sample as used herein is intended to encompass a sample on which any type of device known in the art is being fabricated. Further, for the purposes of the present disclosure, the term sample and wafer should be interpreted as interchangeable. In addition, for the purposes of the present disclosure, the terms patterning device, mask and reticle should be interpreted as interchangeable.

In embodiments, the overlay metrology system 500 includes a metrology sub-system 502 to acquire overlay signals from overlay targets 201 based on any number of overlay recipes. For example, the metrology sub-system 502 may direct illumination to a sample 504 and may further collect light or other radiation emanating from the sample 504 to generate an overlay signal suitable for the determination of overlay of two or more sample layers. The metrology sub-system 502 may be any type of overlay metrology sub-system known in the art suitable for generating overlay signals suitable for determining overlay associated with overlay targets 201 on a sample 504. The metrology sub-system 502 may selectively operate in an imaging mode or a non-imaging mode. For example, in an imaging mode, as discussed previously herein, the overlay target 201 may include one or more meta-lens feature sets 200 configured to generate a periodic distribution of light at the measurement plane 210, where the metrology sub-system 502 may be configured to image the periodic distribution of light at the measurement plane 210. In this regard, the image of the periodic distribution of light at the measurement plane 210 has an enhanced contrast when compared to taking an image of the target itself (as shown in FIG. 1B).

Further, the metrology sub-system 502 may be configurable to generate overlay signals based on any number of recipes defining measurement parameters for acquiring an overlay signal suitable for determining overlay of an overlay target 201. For example, a recipe of an metrology sub-system 502 may include, but is not limited to, an illumination wavelength, a detected wavelength of light emanating from the sample 504, a spot size or shape of illumination on the sample 504, an angle of incident illumination, a polarization of incident illumination, a polarization of collected light, a position of a beam of incident illumination on an overlay target 201, a position of an overlay target 201 in the focal volume of the metrology sub-system 502, or the like.

In embodiments, the metrology sub-system 502 includes an illumination sub-system including an illumination source 514 configured to generate at least one illumination beam 516 and one or more illumination optics 522. For example, the illumination sub-system may include one or more broadband illumination sources 514 configured to generate one or more broadband illumination beams 516. In this regard, the metrology sub-system 502 may include one or more apertures at an illumination pupil plane to divide illumination from the illumination source 514 into one or more illumination beams 516 or illumination lobes. In this regard, the metrology sub-system 502 may provide dipole illumination, quadrature illumination, or the like. Further, the spatial profile of the one or more illumination beams 516 on the sample 504 may be controlled by a field-plane stop to have any selected spatial profile.

The illumination source 514 may include any type of illumination source suitable for providing at least one broadband illumination beam 516. In embodiments, the illumination source 514 is a laser source. For example, the illumination source 514 may include a broadband laser source.

In embodiments, the metrology sub-system 502 directs the illumination beam 516 to the sample 504 via an illumination pathway 518. The illumination pathway 518 may include one or more optical components suitable for modifying and/or conditioning the illumination beam 516 as well as directing the illumination beam 516 to the sample 504. In embodiments, the illumination pathway 518 includes one or more illumination-pathway lenses 520 (e.g., to collimate the illumination beam 516, to relay pupil and/or field planes, or the like). In embodiments, the illumination pathway 518 includes one or more illumination-pathway optics 522 to shape or otherwise control the illumination beam 516. For example, the illumination-pathway optics 522 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

In embodiments, the metrology sub-system 502 includes an objective lens 524 to focus the illumination beam 516 onto the sample 504 (e.g., an overlay target 201 with overlay target features located on two or more layers of the sample 504). In embodiments, the sample 504 is disposed on a sample stage 526 suitable for securing the sample 504 and further configured to position the sample 504 with respect to the illumination beam 516.

FIG. 5B is a conceptual view of the overlay target including the meta-lens feature set, in accordance with one or more embodiments of the present disclosure.

FIG. 5B depicts the lens focus distance F (or focal length F) and a cone 540 representing a numerical aperture of the objective lens 534 of the metrology sub-system 502, where the objective lens 534 has a focal length of f₀. It is contemplated herein, that for a typical setup with an infinity-corrected objective lens, the target features are placed at f₀. However, in the present disclosure as discussed herein, the system is shifted so that f₀ is placed at the measurement plane instead of the sample features. In this regard, the meta-lens feature set 200 operates as a meta-lens array to generate a periodic distribution of light at the measurement plane 210, which may be imaged by the system at the measurement plane 210.

It is contemplated herein that measurement plane 210 may be above or below the meta-lens feature set 200 and may further be within a volume of the sample or outside the sample entirely. Further, it is noted herein that in the case that the target 201 includes multiple sample layers including one or more meta-lens feature sets 200, each meta-lens feature set 200 may have the same or different measurement plane 210. However, it is contemplated herein that having the measurement planes overlap may be beneficial in that it would provide high contrast signals for both layers in a single image.

In embodiments, the metrology sub-system 502 includes one or more detectors 528 configured to capture light emanating from the sample 504 (e.g., an overlay target 201 on the sample 504) (e.g., collected light 530) through a collection pathway 532. The collection pathway 532 may include one or more optical elements suitable for modifying and/or conditioning the collected light 530 from the sample 504. In embodiments, the collection pathway 532 includes one or more collection-pathway lenses 534 (e.g., to collimate the illumination beam 516, to relay pupil and/or field planes, or the like), which may include, but is not required to include, the objective lens 524. In embodiments, the collection pathway 532 includes one or more collection-pathway optics 536 to shape or otherwise control the collected light 530. For example, the collection-pathway optics 536 may include, but are not limited to, one or more field stops, one or more pupil stops, one or more polarizers, one or more filters, one or more beams splitters, one or more diffusers, one or more homogenizers, one or more apodizers, one or more beam shapers, or one or more mirrors (e.g., static mirrors, translatable mirrors, scanning mirrors, or the like).

The detector 528 may be located at any selected location within the collection pathway 532. In embodiments, the metrology sub-system 502 includes the detector 528 configured to generate an image of the periodic distribution of light at the measurement plane 210. In a general sense, the detector 528 may capture any combination of reflected (or transmitted), scattered, or diffracted light from the sample 504.

The metrology sub-system 502 may generally include any number or type of detectors 528 suitable for capturing light from the sample 504 indicative of overlay. In embodiments, the detector 528 includes one or more detectors 528 suitable for characterizing a static sample. In this regard, the metrology sub-system 502 may operate in a static mode in which the sample 504 is static during a measurement. For example, a detector 528 may include a two-dimensional pixel array such as, but not limited to, a charge-coupled device (CCD) or a complementary metal-oxide semiconductor (CMOS) device. In this regard, the detector 528 may generate a two-dimensional image in a single measurement.

In embodiments, the detector 528 includes one or more detectors 528 suitable for characterizing a moving sample 504 (e.g., a scanned sample). In this regard, the metrology sub-system 502 may operate in a scanning mode in which the sample 504 is scanned with respect to a measurement field during a measurement. For example, the detector 528 may include a 2D pixel array with a capture time and/or a refresh rate sufficient to capture one or more images during a scan within selected image tolerances (e.g., image blur, contrast, sharpness, or the like). By way of another example, the detector 528 may include a line-scan detector to continuously generate an image one line of pixels at a time. By way of another example, the detector 528 may include a time-delay integration (TDI) detector. A TDI detector may generate a continuous image of the sample 504 when the motion of the sample 504 is synchronized to charge-transfer clock signals in the TDI detector. In particular, a TDI detector acquires charge from light exposure on columns of pixels and includes clock pulses to transfer charge between adjacent columns of pixels along a scan direction. When the motion of the sample 504 along the scan direction is synchronized to the charge transfer in the TDI detector, charge continuously accumulates during the scan. This process continues until the charge reaches a final column of pixels and is subsequently read out of the detector. In this way, images of the object are accumulated over a longer time frame than would be possible with a simple line scan camera. This relatively longer acquisition time decreases the photon noise level in the image. Further, synchronous motion of the image and charge prevents blurring in the recorded image.

In embodiments, the metrology sub-system 502 includes a scanning sub-system to scan the sample 504 with respect to the measurement field during a metrology measurement. For example, the sample stage 526 may position and orient the sample 504 within a focal volume of the objective lens 524. In embodiments, the sample stage 526 includes one or more adjustable stages such as, but not limited to, a linear translation stage, a rotational stage, or a tip/tilt stage. In embodiments, though not shown, the scanning sub-system includes one or more beam-scanning optics (e.g., rotatable mirrors, galvanometers, or the like) to scan the illumination beams 516 with respect to the sample 504).

The illumination pathway 518 and the collection pathway 532 of the metrology sub-system 502 may be oriented in a wide range of configurations suitable for illuminating the sample 504 with the illumination beams 516 and collecting light emanating from the sample 504 in response to the incident illumination beams 516. For example, as illustrated in FIG. 4, the metrology sub-system 502 may include a beamsplitter 538 oriented such that a common objective lens 524 may simultaneously direct the illumination beams 516 to the sample 504 and collect light from the sample 504. By way of another example, the illumination pathway 518 and the collection pathway 532 may contain non-overlapping optical paths.

In embodiments, the metrology sub-system 502 may provide overlay data to one or more process sub-systems. Overlay data from an overlay metrology sub-system may generally include any output of an overlay metrology sub-system having sufficient information to determine overlay (or overlay errors) associated with various lithography steps. For example, overlay data may include, but is not required to include, one or more datasets, one or more images, one or more detector readings, or the like. This overlay data may then be used for various purposes including, but not limited to, diagnostic information of the lithography sub-systems or for the generation of process-control correctables. For instance, overlay data for samples in a lot may be used to generate feedback correctables for controlling the lithographic exposure of subsequent samples in the same lot. In another instance, overlay data for samples in a lot may be used to generate feed-forward correctables for controlling lithographic exposures for the same or similar samples in subsequent lithography steps to account for any deviations in the current exposure.

In embodiments, the overlay metrology system 500 includes a controller 508. The controller 508 may include one or more processors 510 and/or a memory medium 512 (e.g., memory 512). The controller 508 may include one or more processors 510 configured to execute program instructions maintained on a memory medium 512, or memory. In this regard, the one or more processors 510 of the controller 508 may execute any of the various process steps described throughout the present disclosure. Further, the controller 508 may be communicatively coupled to the metrology sub-system 502 or any component therein.

The one or more processors 510 of a controller 508 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 510 may include any device configured to execute algorithms and/or instructions (e.g., program instructions stored in memory). In embodiments, the one or more processors 510 may be embodied as a desktop computer, mainframe computer system, workstation, image computer, parallel processor, networked computer, or any other computer system configured to execute a program configured to operate or operate in conjunction with the overlay metrology system 500, as described throughout the present disclosure.

Moreover, different subsystems of the overlay metrology system 500 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller 508 or, alternatively, multiple controllers. Additionally, the controller 508 may include one or more controllers housed in a common housing or within multiple housings. In this way, any controller or combination of controllers may be separately packaged as a module suitable for integration into the overlay metrology system 500.

The memory medium 512 may include any storage medium known in the art suitable for storing program instructions executable by the associated one or more processors 510. For example, the memory medium 512 may include a non-transitory memory medium. By way of another example, the memory medium 512 may include, but is not limited to, a read-only memory (ROM), a random-access memory (RAM), a magnetic or optical memory device (e.g., disk), a magnetic tape, a solid-state drive and the like. It is further noted that memory medium 512 may be housed in a common controller housing with the one or more processors 510. In embodiments, the memory medium 512 may be located remotely with respect to the physical location of the one or more processors 510 and controller 508. For instance, the one or more processors 510 of controller 508 may access a remote memory (e.g., server), accessible through a network (e.g., internet, intranet, and the like).

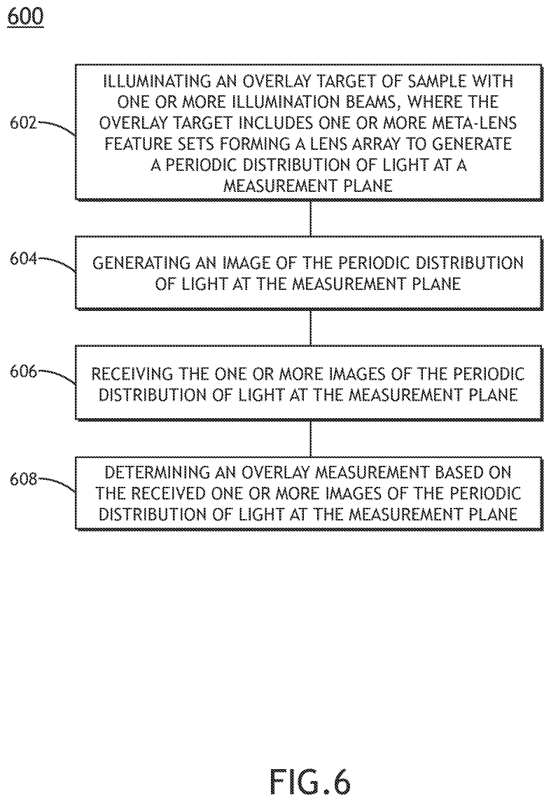

FIG. 6 is a flowchart depicting a method 600 for measuring overlay, in accordance with one or more embodiments of the present disclosure. Applicant notes that the embodiments and enabling technologies described previously herein in the context of the overlay metrology system 500 should be interpreted to extend to the method 600. It is further noted, however, that the method 600 is not limited to the architecture of the overlay metrology system 500.

In embodiments, the method 600 includes a step 602 of illuminating a sample with one or more broadband illumination beams, where an overlay metrology target of the sample includes one or more meta-lens feature sets forming a lens array. The lens array may generate a periodic distribution of light at a measurement plane 210. In embodiments, the duty cycle of the second features 206 may be adjusted to resemble a lens phase distribution, where the lens phase distribution is based on a lens focus distance.

In embodiments, the method 600 includes a step 604 of generating an image of the periodic distribution of light at the measurement plane.

In embodiments, the method 600 includes a step 606 of receiving one or more images of the periodic distribution of light at the measurement plane from one or more detectors.

In embodiments, the method 600 includes a step 608 of determining an overlay measurement of the sample based on the images of the periodic distribution of light at the measurement plane. In this regard, measurement of the process compatible overlay target 201 is measurable due to the enhanced contrast of the periodic distribution of light at the measurement plane 210 (rather than an image of the sample features), thereby improving accuracy of overlay measurement.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken as limiting.

Those having skill in the art will appreciate that there are various vehicles by which processes and/or systems and/or other technologies described herein can be implemented (e.g., hardware, software, and/or firmware), and that the preferred vehicle will vary with the context in which the processes and/or systems and/or other technologies are deployed. For example, if an implementer determines that speed and accuracy are paramount, the implementer may opt for a mainly hardware and/or firmware vehicle; alternatively, if flexibility is paramount, the implementer may opt for a mainly software implementation; or, yet again alternatively, the implementer may opt for some combination of hardware, software, and/or firmware. Hence, there are several possible vehicles by which the processes and/or devices and/or other technologies described herein may be effected, none of which is inherently superior to the other in that any vehicle to be utilized is a choice dependent upon the context in which the vehicle will be deployed and the specific concerns (e.g., speed, flexibility, or predictability) of the implementer, any of which may vary.

The previous description is presented to enable one of ordinary skill in the art to make and use the invention as provided in the context of a particular application and its requirements. As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An overlay metrology target comprising:
one or more first exposure structures; and
one or more second exposure structures, wherein at least one of the one or more first exposure structures or the one or more second exposure structures include one or more meta-lens feature sets,
wherein each meta-lens feature set comprises:
one or more first features having a coarse pitch; and
one or more second features having a fine pitch, wherein the one or more second features are positioned relative to the one or more first features, wherein the fine pitch is smaller than the coarse pitch,
wherein the one or more first features and the one or more second features of each meta-lens feature set operates as a meta-lens array to generate a periodic distribution of light at a measurement plane different than a plane of at least one of the one or more meta-lens feature sets, wherein the periodic distribution of light has the coarse pitch.

2. The overlay metrology target of claim 1, wherein a duty cycle of the one or more second features are varied to resemble a lens phase distribution, wherein the lens phase distribution provides a lens focus distance.

3. The overlay metrology target of claim 2, wherein the measurement plane is arranged at the lens focus distance.

4. The overlay metrology target of claim 1, wherein the one or more first features have a first set of critical dimension values, wherein the one or more second features have a second set of critical dimension values different from the first set of critical dimension values.

5. The overlay metrology target of claim 1, wherein the one or more first features and the one or more second features include two-dimensional features.

6. The overlay metrology target of claim 5, wherein the two-dimensional features include two-dimensional circular inclusions.

7. The overlay metrology target of claim 1, wherein the one or more first exposure structures and the one or more second exposure structures are non-overlapping.

8. The overlay metrology target of claim 1, wherein the one or more first exposure structures are on a first layer of a sample and the one or more second exposure structures are on a second layer of the sample.

9. The overlay metrology target of claim 8, wherein the first layer includes a process layer and the second layer includes a resist layer.

10. The overlay metrology target of claim 9, wherein the one or more first exposure structures of the process layer include the one or more meta-lens feature sets.

11. The overlay metrology target of claim 9, wherein the one or more second exposure structures of the resist layer include the one or more meta-lens feature sets.

12. The overlay metrology target of claim 9, wherein the one or more first exposure structures of the process layer and the one or more second exposure structures of the resist layer include the one or more meta-lens feature sets.

13. A meta-lens feature set comprising:
one or more first features having a coarse pitch; and
one or more second features having a fine pitch, wherein the one or more second features are positioned relative to the one or more first features, wherein the fine pitch is smaller than the coarse pitch,
wherein the one or more first features and the one or more second features operates as a meta-lens array to generate a periodic distribution of light at a measurement plane different than a plane of the meta-lens feature set, wherein the periodic distribution of light has the coarse pitch.

14. The meta-lens feature set of claim 13, wherein a duty cycle of the one or more second features are varied to resemble a lens phase distribution, wherein the lens phase distribution provides a lens focus distance.

15. An overlay metrology system comprising:
an illumination sub-system comprising:
one or more broadband illumination sources configured to generate one or more broadband illumination beams; and
one or more illumination optics configured to direct the one or more broadband illumination beams to an overlay target on a sample when implementing a metrology recipe, wherein the overlay target in accordance with the metrology recipe includes one or more meta-lens feature sets, wherein each meta-lens feature set includes one or more first features having a coarse pitch and one or more second features having a fine pitch, wherein the one or more first features and the one or more second features of each meta-lens feature set operates as a meta-lens array to generate a periodic distribution of light at a measurement plane different than a plane of at least one of the one or more meta-lens feature sets, wherein the periodic distribution of light has the coarse pitch;
a collection sub-system comprising:
a detector configured to generate one or more images of the periodic distribution of light at the measurement plane; and
one or more collection optics; and
a controller communicatively coupled to the detector, the controller including one or more processors configured to execute program instructions causing the one or more processors to:
receive the one or more images of the periodic distribution of light at the measurement plane from the detector; and
generate an overlay measurement of the sample based on the one or more images of the periodic distribution of light at the measurement plane.

16. The overlay metrology system of claim 15, wherein the one or more processors are further configured to execute program instructions causing the one or more processors to:
adjusting a duty cycle of the one or more second features to resemble a lens phase distribution, wherein the lens phase distribution provides a lens focus distance.

17. The overlay metrology system of claim 16, wherein the measurement plane is arranged at the lens focus distance.

18. The overlay metrology system of claim 15, wherein the one or more first features and the one or more second features include two-dimensional features.

19. An overlay metrology system comprising:
a controller communicatively coupled to a detector, the controller including one or more processors configured to execute program instructions causing the one or more processors to:
receive one or more images of a periodic distribution of light at a measurement plane from the detector, wherein a overlay target in accordance with a metrology recipe includes one or more meta-lens feature sets, wherein each meta-lens feature set includes one or more first features having a coarse pitch and one or more second features having a fine pitch, wherein the one or more first features and the one or more second features of each meta-lens feature set operates as a meta-lens array to generate the periodic distribution of light at the measurement plane different than a plane of at least one of the one or more meta-lens feature sets, wherein the periodic distribution of light has the coarse pitch; and
generate an overlay measurement of a sample based on the one or more images of the periodic distribution of light at the measurement plane.

20. The overlay metrology system of claim 19, wherein the one or more processors are further configured to execute program instructions causing the one or more processors to:
adjust a duty cycle of the one or more second features to resemble a lens phase distribution, wherein the lens phase distribution provides a lens focus distance.

21. The overlay metrology system of claim 20, wherein the measurement plane is arranged at the lens focus distance.

22. A method comprising:
illuminating an overlay target of a sample with one or more broadband illumination beams from one or more broadband illumination sources, wherein the overlay target in accordance with a metrology recipe includes one or more meta-lens feature sets, wherein each meta-lens feature set includes one or more first features having a coarse pitch and one or more second features having a fine pitch, wherein the one or more first features and the one or more second features of each meta-lens feature set operates as a meta-lens array to generate a periodic distribution of light at a measurement plane different than a plane of at least one of the one or more meta-lens feature sets, wherein the periodic distribution of light has the coarse pitch;
generating one or more images of the periodic distribution of light at the measurement plane;
receiving the one or more images of the periodic distribution of light at the measurement plane; and
generating an overlay measurement of the sample based on the one or more images of the periodic distribution of light at the measurement plane.

23. The method of claim 22, further comprising:
adjusting a duty cycle of the one or more second features to resemble a lens phase distribution, wherein the lens phase distribution provides a lens focus distance.

24. The method of claim 23, wherein the measurement plane is arranged at the lens focus distance.
